(19) United States
(12) Patent Application Publication
(10) Pub. No.: US 2012/0267639 A1
(43) Pub. Date: Oct. 25, 2012

(54) NITRIDE SEMICONDUCTOR DEVICE AND METHOD FOR MANUFACTURING THE SAME

(75) Inventors: Woo Chul JEON, Gyeonggi-do (KR); Ki Yeol Park, Gyeonggi-do (KR); Young Hwan Park, Seoul (KR)

(73) Assignee: Samsung Electro-Mechanics Co., Ltd., Suwon (KR)

(21) Appl. No.: 13/448,678

(22) Filed: Apr. 17, 2012

(30) Foreign Application Priority Data
Apr. 25, 2011 (KR) 10-2011-0038613

(51) Int. Cl. H01L 29/778; H01L 21/336; H01L 29/205

(52) U.S. Cl. 257/76; 257/194; 438/257; 257/E29.246; 257/E29.091; 257/E21.403

(57) ABSTRACT

Disclosed herein are a nitride semiconductor device and a method for manufacturing the same. According to an exemplary embodiment, there is provided a nitride semiconductor device, including: a nitride semiconductor layer having a 2DEG channel; a drain electrode ohmic-contacted with the nitride semiconductor layer; a source electrode Schottky-contacted with the nitride semiconductor layer, including a plurality of patterned protrusion portions protruded to the drain electrode direction, and including an ohmic pattern ohmic-contacted with the nitride semiconductor layer therein; a dielectric layer disposed on the nitride semiconductor layer between the drain electrode and the source electrode and over at least a portion of the source electrode including the patterned protrusion portions; and a gate electrode disposed on the dielectric, wherein a portion of the gate electrode is disposed on the dielectric layer over the patterned protrusion portions and a drain direction edge portion of the source electrode.

### CROSS REFERENCE(S) TO RELATED APPLICATIONS

This application claims the benefit under 35 U.S.C. Section 119 of Korean Patent Application Serial No. 10-2011-0038613, entitled “Nitride Semiconductor Device and Method for Manufacturing the Same” filed on Apr. 25, 2011, which is hereby incorporated by reference in its entirety into this application.

### BACKGROUND OF THE INVENTION

1. Technical Field

The present invention relates to a nitride semiconductor device and a method for manufacturing the same. More particularly, the present invention relates to a normally-off operating nitride semiconductor device and a method for manufacturing the same.

2. Description of the Related Art

An interest in saving power consumption has been increased due to a green energy policy, or the like. To this end, there is a need to increase power conversion efficiency. For the power conversion, the overall power conversion efficiency depends on an efficiency of a power switching device.

Today, as power devices generally used, a power MOSFET or an IGBT using silicon has been mainly used. However, there is a limitation in increasing efficiency in devices due to a limitation of a silicon material. To resolve the above problems, patents for increasing conversion efficiency by manufacturing a transistor using a nitride semiconductor such as gallium nitride (GaN) have been filed.

However, for example, a high electron mobility transistor (HEMT) structure using GaN is in a ‘turn-on’ state in which current flows due to low resistance between a drain electrode and a source electrode when a gate voltage is 0V (normal state). Therefore, current and power are consumed. In order to turn-off the high electron mobility transistor, there is a need to apply negative voltage (for example, −5V) to a gate electrode (normally-on structure).

In order to solve the disadvantages of the normally-on structure, patent applications as shown in FIGS. 7 and 8 have been proposed as the related arts FIGS. 7 and 8 show the high electron mobility HEMT structure according to the related art.

FIG. 7 corresponds to a drawing disclosed in US Laid-Open Patent No. 2007-0295993. In FIG. 7, a concentration of a channel formed in growing an AlGaN layer 133 is controlled by injecting ions a lower region of a gate G and a region adjacent to a gate electrode G between a gate G and a drain D in the AlGaN layer. In FIG. 7, a normally-off operation is implemented by controlling a carrier concentration of a lower channel region 131 on the gate G using ion implantation.

FIG. 8 corresponds to a drawing disclosed in U.S. Pat. No. 7,038,253. An insulating layer 140 is coated on a channel layer 131 disposed between first and second electron donating layers 133a and 133b and the gate electrode G is disposed on an insulating layer 140, such that a 2DEG channel 135 is not formed on the lower portion of the gate electrode G. In FIG. 8, the normally-off operation is implemented by etching the lower portion of the gate G using a recess process.

There is a need to solve the problem of the above-mentioned normally-on structure and implement the normally-off operating semiconductor device.

### SUMMARY OF THE INVENTION

An object of the present invention is to provide a semiconductor device capable of being operated in a normally-off (N-off) or an enhancement mode and operated at high withstand voltage and high current by forming a Schottky electrode in a source region of a semiconductor device, for example, an FET, providing a plurality of patterned protrusion portions protruded in a drain direction in the source electrode, and providing ohmic pattern electrodes ohmic-contacted at an interface surface of a lower end thereof in the source electrode, and forming a portion of a gate electrode on an upper portion of a portion of the region of a source electrode, and a method for manufacturing the same.

According to an exemplary embodiment of the present invention, there is provided a nitride semiconductor device, including: a nitride semiconductor layer that is disposed over a substrate and has a two dimensional electron gas (2DEG) channel formed therein; a drain electrode that is ohmic-contacted with the nitride semiconductor layer; a source electrode that is disposed to be spaced apart from the drain electrode, includes a plurality of patterned protrusion portions protruded to the drain electrode direction, is Schottky-contacted with the nitride semiconductor layer, and includes an ohmic pattern ohmic-contacted with the nitride semiconductor layer therein; a dielectric layer that is disposed on the nitride semiconductor layer between the drain electrode and the source electrode and over at least a portion of the source electrode, wherein the portion of the source electrode includes the patterned protrusion portions; and a gate electrode that is disposed on the dielectric layer so as to be spaced apart from the drain electrode, wherein a portion of the gate electrode is disposed on the dielectric layer over the patterned protrusion portions and a drain direction edge portion of the source electrode.

A portion of at least a drain direction side of the ohmic pattern may be contacted with the dielectric layer on at least wall sections of the recess regions formed by the plurality of patterned protrusion portions. A portion in the drain direction of the ohmic pattern may be contacted with the dielectric layer in the recess regions formed by the plurality of patterend protrusion portions.

A portion of the gate electrode formed over the patterned protrusion portions and the drain direction edge portion may be formed to cover at least a portion of the ohmic pattern of the source electrode.

The ohmic pattern may be disposed in parallel with an arrangement of the drain electrode.

The nitride semiconductor layer may include: a first nitride layer that is disposed over the substrate and includes a gallium nitride based material; and a second nitride layer that is heterogeneous-junctioned on the first nitride layer and contains a heterogeneous gallium nitride based material having an energy bandgap wider than that of the first nitride layer.

The first nitride layer may contain gallium nitride (GaN), and the second nitride layer may contain any one of aluminum gallium nitride (AlGaN), indium gallium nitride (InGaN), and indium aluminum gallium nitride (InAlGaN).

According to another exemplary embodiment of the present invention, there is provided a nitride semiconductor device, including: a nitride semiconductor layer that is disposed over a substrate and has a two dimensional electron gas (2DEG) channel formed therein; a drain electrode that is ohmic-contacted with the nitride semiconductor layer; a source electrode that is disposed to be spaced apart from the drain electrode, includes a plurality of patterned protrusion portions protruded to the drain electrode direction, is Schottky-contacted with the nitride semiconductor layer, and includes an ohmic pattern ohmic-contacted with the nitride semiconductor layer therein; a dielectric layer that is disposed on the nitride semiconductor layer between the drain electrode and the source electrode and over at least a portion of the source electrode, wherein the portion of the source electrode includes the patterned protrusion portions; and a gate electrode that includes a first region formed on the dielectric layer over the patterned protrusion portions and a drain direction edge portion of the source electrode and a second region disposed on the dielectric layer between the drain electrode and the source electrode so as to be spaced apart from the drain electrode.

A portion of at least the drain direction side of the ohmic pattern may be contacted with the dielectric layer on at least wall sections of the recess regions formed by the plurality of patterned protrusion portions.

A portion in the drain direction of the ohmic pattern may be contacted with the dielectric layer in the recess regions formed by the plurality of patterend protrusion portions.

The gate electrode may be separated into the first region and the second region, wherein the second region forms a floating gate.

The first region may be formed to cover at least a portion of the ohmic pattern of the source electrode.

The ohmic pattern may be disposed in parallel with an arrangement of the drain electrode.

The nitride semiconductor layer may include: a first nitride layer that is disposed over the substrate and includes a gallium nitride based material; and a second nitride layer that is heterogeneous-junctioned on the first nitride layer and contains a heterogeneous gallium nitride based material having an energy bandgap wider than that of the first nitride layer.

The first nitride layer may contain gallium nitride (GaN), and the second nitride layer may contain any one of aluminum gallium nitride (AlGaN), indium gallium nitride (InGaN), and indium aluminum gallium nitride (InAlGaN).

The nitride semiconductor device may further include a buffer layer between the substrate and the nitride semiconductor layer.

The substrate may use at least any one of silicon (Si), silicon carbide (SiC), and sapphire (Al₂O₃).

The dielectric layer may be made of at least any one of SiN, SiO₂, and Al₂O₃.

The nitride semiconductor device may be a power transistor device.

According to another exemplary embodiment of the present invention, there is provided a method for manufacturing a nitride semiconductor device, including: generating a nitride semiconductor layer that is disposed over a substrate and has a two dimensional electron gas (2DEG) channel formed therein; forming a drain electrode that is ohmic-contacted with the nitride semiconductor layer and forming a source electrode that is disposed to be spaced apart from the drain electrode, includes a plurality of patterned protrusion portions protruded to the drain electrode direction, is Schottky-contacted with the nitride semiconductor layer, and includes an ohmic pattern ohmic-contacted with the nitride semiconductor layer therein; forming a dielectric layer that is disposed on the nitride semiconductor layer between the drain electrode and the source electrode and over at least a portion of the source electrode, wherein the portion of the source electrode includes the patterned protrusion portions; and forming a gate electrode on the dielectric layer so as to be spaced apart from the drain electrode, wherein a portion of the gate electrode is formed on the dielectric layer over the patterned protrusion portions and on a drain direction edge portion of the source electrode.

At the forming of the source electrode, a portion of at least a drain direction side of the ohmic pattern may be exposed on at least wall sections of the recess regions formed by the plurality of patterned protrusion portions, and at the forming of the dielectric layer, the dielectric layer may be formed so that the exposed portion of at least the drain direction side of the ohmic pattern is contacted with the dielectric layer. At the forming of the source electrode, a portion in the drain direction of the ohmic pattern may be exposed in the recess regions formed by the plurality of patterned protrusion portions, and at the forming of the dielectric layer, the dielectric layer may be formed so that the exposed portion in the drain direction of the ohmic pattern is contacted with the dielectric layer.

At the forming of the gate electrode, a portion of the gate electrode formed over the patterned protrusion portions and the drain direction edge portion of the source electrode may be formed so as to cover at least a portion of the ohmic pattern of the source electrode.

At the forming of the source electrode, the ohmic pattern may be disposed in parallel with an arrangement of the drain electrode.

The forming of the nitride semiconductor layer may include forming a first nitride layer including a gallium nitride based material on the upper portion of the substrate by an epitaxial growth; and forming a second nitride layer including a heterogeneous gallium nitride based material having an energy bandgap wider than that of the first nitride layer using the first nitride layer as a seed layer by the epitaxial growth.

According to another exemplary embodiment of the present invention, there is provided a method for manufacturing a nitride semiconductor device, including: generating a nitride semiconductor layer that is disposed over a substrate and has a two dimensional electron gas (2DEG) channel formed therein; forming a drain electrode that is ohmic-contacted with the nitride semiconductor layer and forming a source electrode that is disposed to be spaced apart from the drain electrode, includes a plurality of patterned protrusion portions protruded to the drain electrode direction, is Schottky-contacted with the nitride semiconductor layer, and includes an ohmic pattern ohmic-contacted with the nitride semiconductor layer therein; forming a dielectric layer that is disposed on the nitride semiconductor layer between the drain electrode and the source electrode and over at least a portion of the source electrode, wherein the portion of the source electrode includes the patterned protrusion portions; and forming a gate electrode that includes a first region formed on the dielectric layer over the patterned protrusion portions and a drain direction edge portion of the source electrode and a second region disposed on the dielectric layer between the drain electrode and the source electrode so as to be spaced apart from the drain electrode.

At the forming of the source electrode, a portion of at least the drain direction side of the ohmic pattern may be exposed on at least wall sections of the recess regions formed by the plurality of patterned protrusion portions, and at the forming of the dielectric layer, the dielectric layer may be formed so that the exposed portion of at least the drain direction side of the ohmic pattern is contacted with the dielectric layer.

At the forming of the source electrode, a portion in the drain direction of the ohmic pattern may be exposed in the recess regions formed by the plurality of patterned protrusion portions, and at the forming of the dielectric layer, the dielectric layer may be formed so that the exposed portion in the drain direction of the ohmic pattern is contacted with the dielectric layer. At the forming of the gate electrode, the gate electrode may be formed by separating the first region from the second region, wherein the second region is formed as the floating gate on the dielectric layer between the drain electrode and the source electrode.

At the forming of the gate electrode, the first region is formed to cover at least a portion of the ohmic pattern of the source electrode.

Although not specifically stated as an aspect of the present invention, exemplary embodiments of the present invention according to possible various combinations of above-mentioned technical characteristics may be supported by the following specific exemplary embodiments and may be obviously implemented by those skilled in the art.

### BRIEF DESCRIPTION OF THE DRAWINGS

FIG. 1 is a schematic plan view of a nitride semiconductor device according to an exemplary embodiment of the present invention.

FIGS. 2A and 2B are cross-sectional views of interval I-I′ and interval II-II′ of the nitride semiconductor device shown in FIG. 1.

FIGS. 3A to 3D are diagrams schematically showing a method for manufacturing the nitride semiconductor device shown in FIG. 2A.

FIGS. 4A to 4D are diagrams schematically showing a method for manufacturing the nitride semiconductor device shown in FIG. 2B.

FIGS. 5A and 5B are schematic cross-sectional views of a nitride semiconductor device according to another exemplary embodiment of the present invention.

FIGS. 6A and 6B are schematic cross-sectional views of a nitride semiconductor device according to another exemplary embodiment of the present invention.

FIGS. 7 and 8 show the high electron mobility HEMT structure according to the related art.

### DESCRIPTION OF THE PREFERRED EMBODIMENTS

Exemplary embodiments of the present invention for accomplishing the above-mentioned objects will be described with reference to the accompanying drawings. In describing exemplary embodiments of the present invention, the same reference numerals will be used to describe the same components and an additional description that is overlapped or allow the meaning of the present invention to be restrictively interpreted will be omitted.

It will be understood that when an element is simply referred to as being ‘connected to’ or ‘coupled to’ another element without being ‘directly connected to’ or ‘directly coupled to’ another element in the present description, it may be ‘directly connected to’ or ‘directly coupled to’ another element or be connected to or coupled to another element, having the other element intervening therebetween. Addition, in the specification, spatially relative terms, ‘on’, ‘over’, ‘above’, ‘upper’, ‘below’, ‘lower’, or the like, they should be interpreted as being in a ‘direct-contact’ shape or a shape in which other elements may be interposed therebetween, without a description that an element is in a ‘direct-contact’ with an object to be a basis. Furthermore, the spatially relative terms, ‘on’, ‘over’, ‘above’, ‘upper’, ‘below’, ‘lower’, or the like, may be used for describing a relationship of an element for another element. In this case, when a direction of the element to be a basis is reversed or changed, the spatially relative terms may include concept for directions of relative terms corresponding thereto.

Although a singular form is used in the present description, it may include a plural form as long as it is opposite to the concept of the present invention and is not contradictory in view of interpretation or is used as clearly different meaning. It should be understood that “include”, “have”, “comprise”, “be configured to include”, and the like, used in the present description do not exclude presence or addition of one or more other characteristic, component, or a combination thereof.

In addition, the drawings referred to in the specification are ideal views for explaining embodiments of the present invention. In the drawings, the sizes, the thicknesses, or the like of films, layers, regions or the like may be exaggerated for clarity. Furthermore, the shapes of the illustrated regions in the drawings are for illustrating specific shapes and are not for limiting the scope of the present invention.

Hereinafter, a semiconductor device and a method for manufacturing the same according to exemplary embodiments of the present invention will be described in more detail with reference to the accompanying drawings.

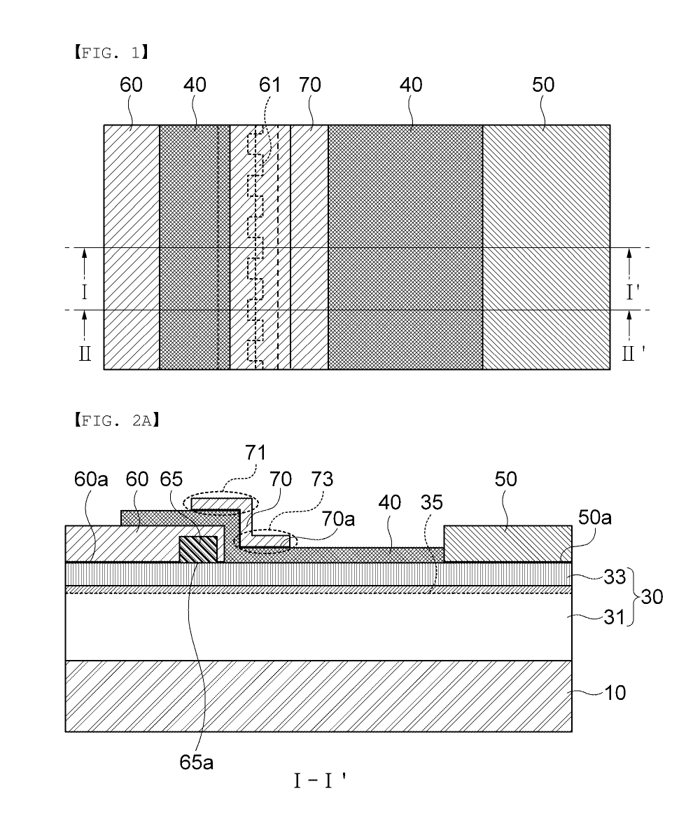

FIG. 1 is a schematic plan view of a nitride semiconductor device according to an exemplary embodiment of the present invention.

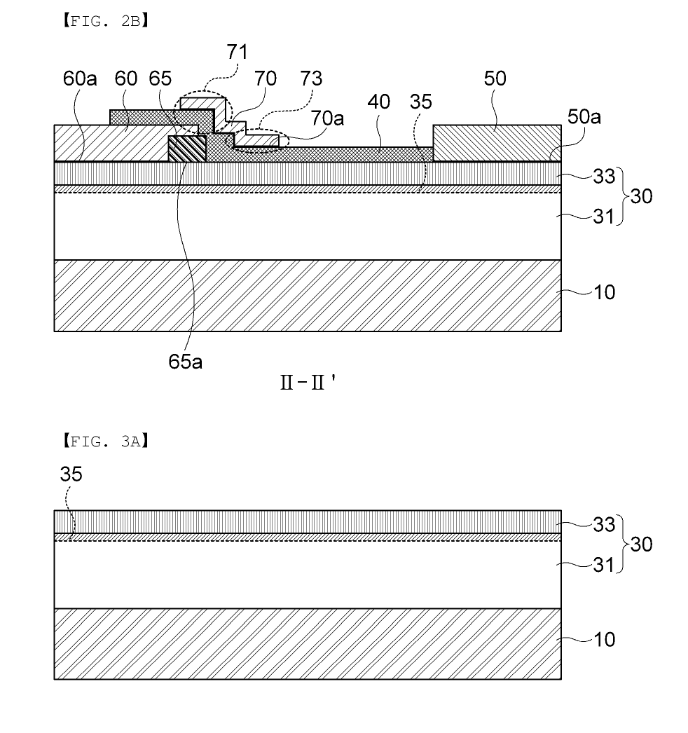

FIGS. 2A and 2B are cross-sectional views of interval I-I′ and interval II-II′ of the nitride semiconductor device shown in FIG. 1.

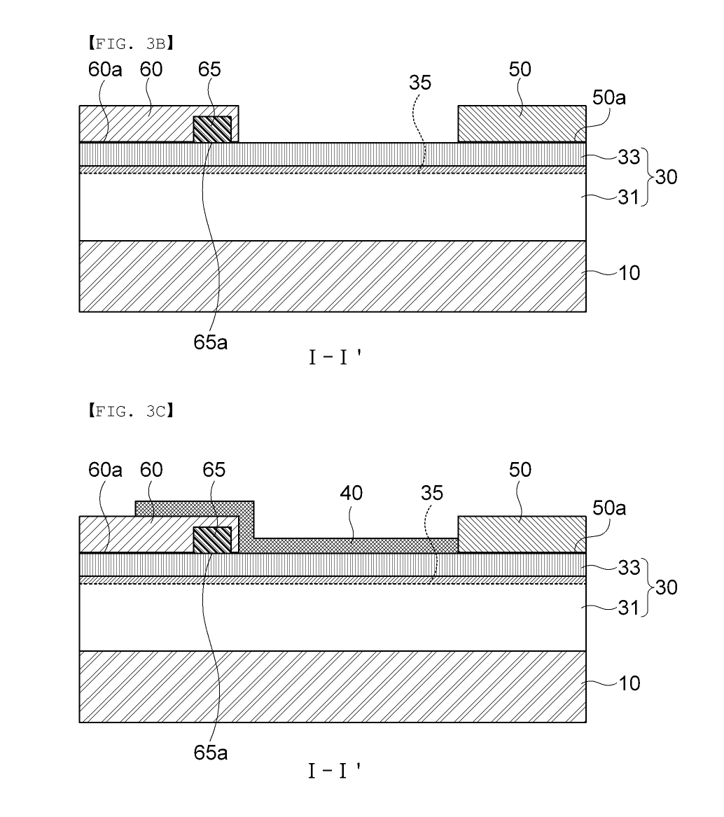

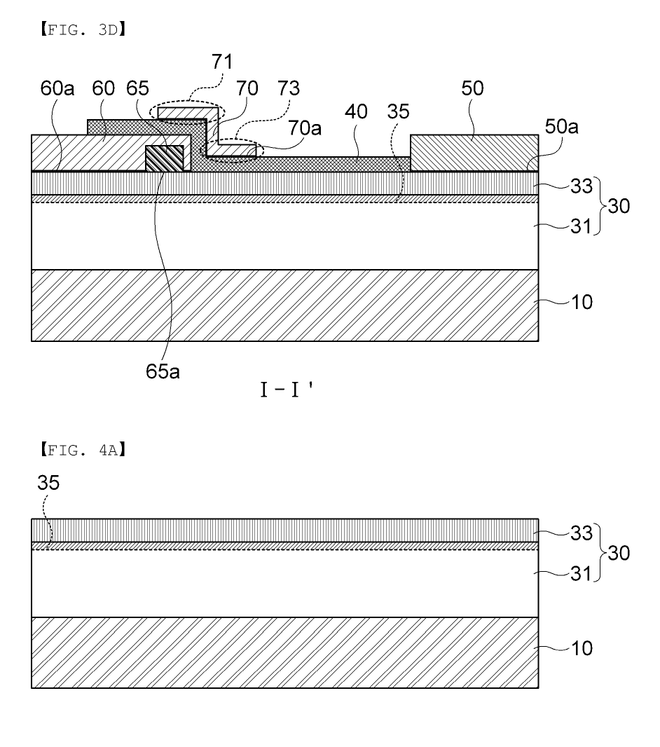

FIGS. 3A to 3D are diagrams schematically showing a method for manufacturing the nitride semiconductor device shown in FIG. 2A.

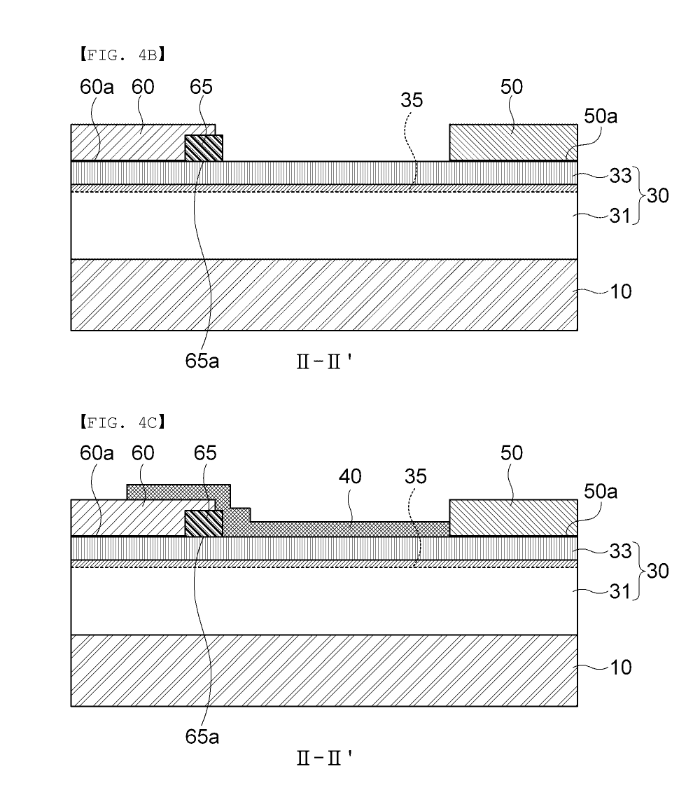

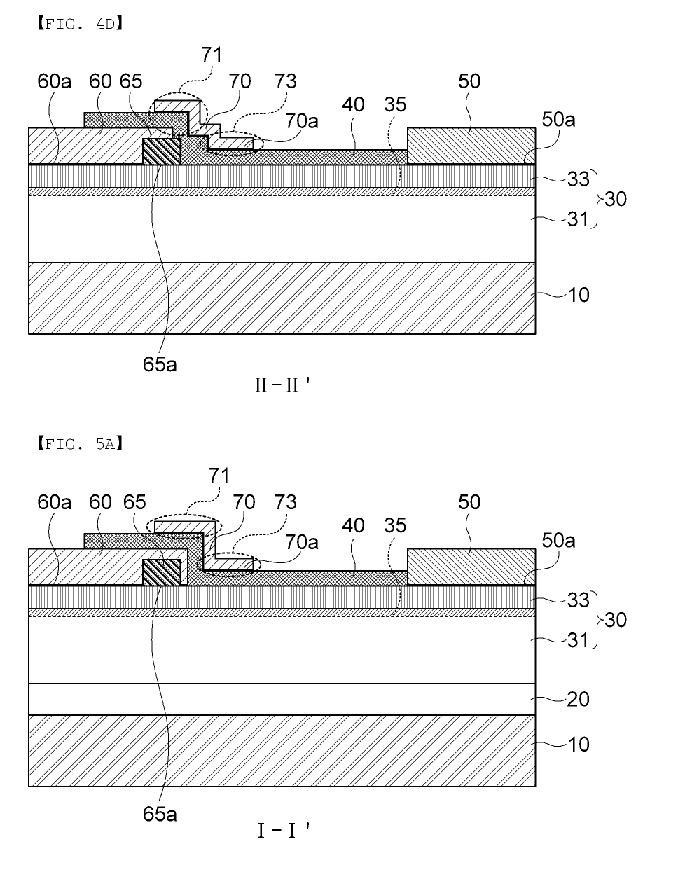

FIGS. 4A to 4D are diagrams schematically showing a method for manufacturing the nitride semiconductor device shown in FIG. 2B.

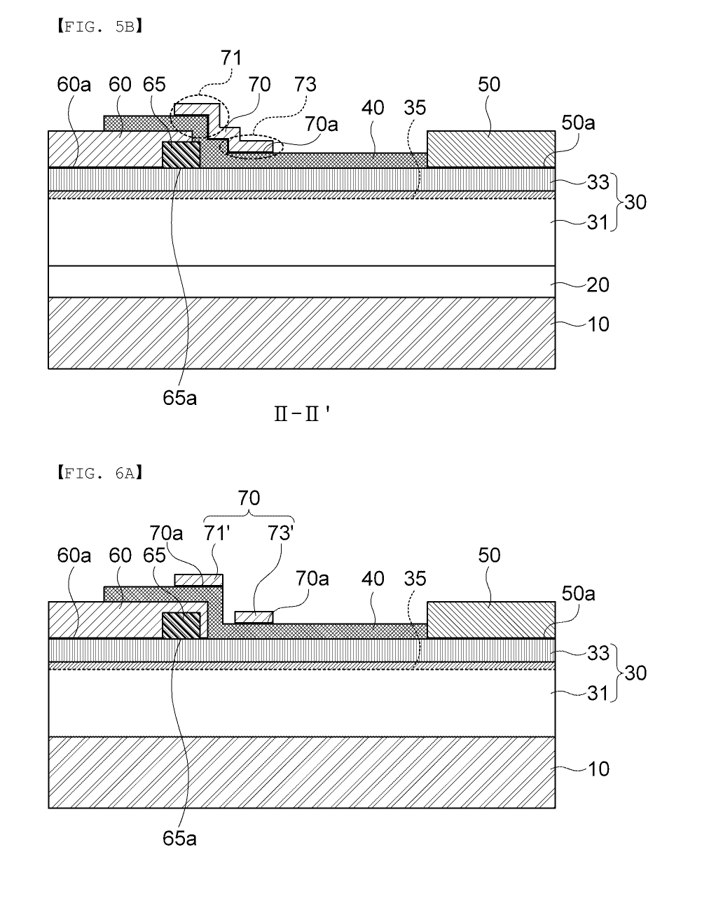

FIGS. 5A and 5B are schematic cross-sectional views of a nitride semiconductor device according to another exemplary embodiment of the present invention and shows a state in which the nitride semiconductor device is cut at positions such as interval I-I′ and II-II′ interval of FIG. 1.

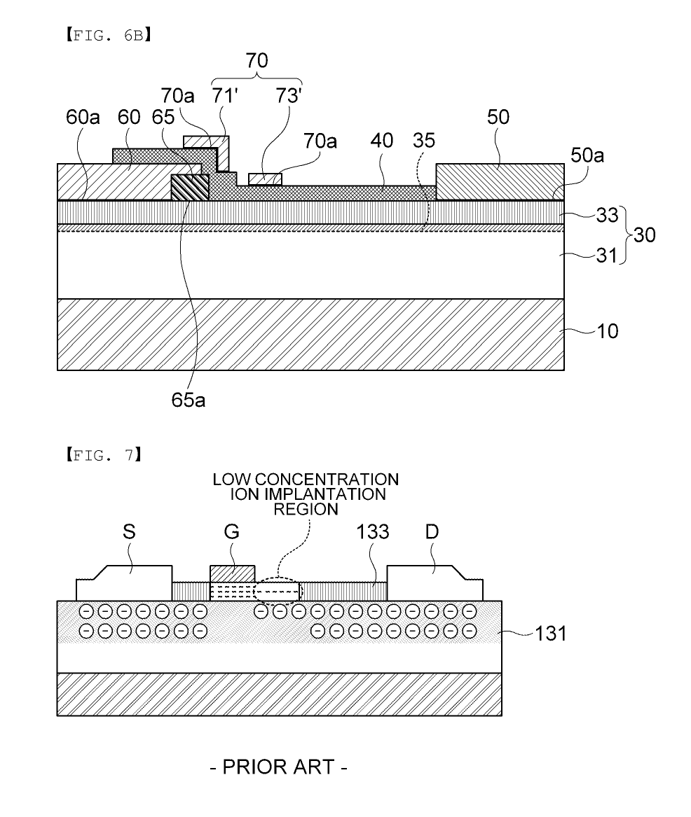

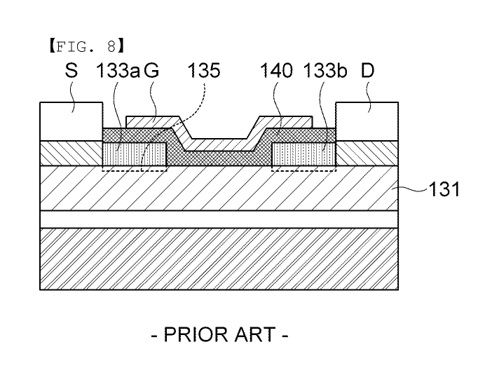

FIGS. 6A and 6B are schematic cross-sectional views of a nitride semiconductor device according to another exemplary embodiment of the present invention and each shows a state in which the nitride semiconductor device is cut at positions such as interval I-I′ and interval II-II′ of FIG. 1.

First, a nitride semiconductor device according to an exemplary embodiment of the present invention will be described in detail with reference to FIGS. 1, 2A and 2B, 5A and 5B, or/and 6A and 6B.

Referring to FIGS. 1, 2A and 2B, or/and 6A and 6B, the nitride semiconductor device according to the exemplary embodiment of the present invention is configured to include a nitride semiconductor layer 30, a drain electrode 50, a source electrode 60, a dielectric layer 40, and a gate electrode 70 which are disposed over a substrate 10.

Referring to FIGS. 2A and 2B or/and FIGS. 6A and 6B, in the exemplary embodiment of the present invention, the nitride semiconductor layer 30 is disposed over the substrate 10. The substrate 10 generally uses an insulating substrate but may use a high resistive substrate that substantially has insulation.

According to another exemplary embodiment of the present invention, in FIGS. 2A and 2B or/and 6A and 6B, the substrate 10 may be made of at least any one of silicon (Si), silicon carbide (SiC), and sapphire (Al₂O₃), or other well-known substrate materials.

The nitride semiconductor layer 30 may be directly disposed over the substrate 10. Preferably, the nitride semiconductor layer 30 may be formed by epitaxially growing a nitride single crystal thin film. As an epitaxial growth process for forming the nitride semiconductor layer 30, liquid phase epitaxy (LPE), chemical vapor deposition (CVD), molecular beam epitaxy (MBE), metalorganic CVD (MOCVD), or the like, may be used.

In addition, referring to FIGS. 5A and 5B, according to another exemplary embodiment of the present invention, a buffer layer 20 may be disposed between the substrate 10 and the nitride semiconductor layer 30 and the nitride semiconductor layer 30 may be disposed on the buffer layer 20. The buffer layer 20 is provided to solve problems due to a lattice mismatch between the substrate 10 and the nitride semiconductor layer 30. The buffer layer 20 may be formed in a single layer or several layers including gallium nitride (GaN), aluminum gallium nitride (AlGaN), aluminum nitride (AlN), indium gallium nitride (InGaN), indium aluminum gallium nitride (InAlGaN), or the like. In addition, the buffer layer 20 may be made of a III-V group compound semiconductor other than gallium nitride. For example, when the substrate 10 is a sapphire substrate, the growth of the buffer layer 20 becomes important so as to prevent a mismatch due to a difference in a lattice constant and a thermal expansion coefficient with the nitride semiconductor layer 30 including gallium nitride.

Referring to FIGS. 2A and 2B, 5A and 5B, or/and 6A and 6B, a two-dimensional electron gas (2DEG) channel 35 is formed in the nitride semiconductor layer 30. When bias voltage is applied to the gate electrode 70 of the nitride semiconductor device, electrons move through the 2DEG channel 35 in the nitride semiconductor layer 30 and current flows between the drain electrode 50 and the source electrode 60. As the nitride forming the nitride semiconductor layer 30, gallium nitride (GaN), aluminum gallium nitride (AlGaN), indium gallium nitride (InGaN), or indium aluminum gallium nitride (InAlGaN), or the like, may be used.

According to the exemplary embodiment of the present invention, the nitride semiconductor layer 30 is a heterogeneous-junctioned gallium nitride based semiconductor layer 30, wherein the two-dimensional electron gas channel 35 is formed due to a difference in an energy bandgap at a heterogeneous-junctioned interface surface. In the heterogeneous-junctioned gallium nitride based semiconductor layer 30, the difference in the lattice constant between the hetro-junctions is reduced and the difference in polarity with the bandgap is reduced accordingly, thereby suppressing the formation of the 2DEG channel 35. At the time of the heterogeneous junction, free electrons move from a material having a wide bandgap to a material having a small bandgap due to the discontinuity of the energy bandgap. These electrons are accumulated at the heterogeneous-junctioned interface surface to form the 2DEG channel 35, such that current may flow between the drain electrode 50 and the source electrode 60.

Referring to FIGS. 2A and 2B, 5A and 5B, or/and 6A and 6B, the nitride semiconductor layer 30 includes a first nitride layer 31 and a second nitride layer 33. The first nitride layer 31 is disposed over the substrate 10 and contains gallium nitride based material. The second nitride layer 33 is heterogeneous-junctioned on the first nitride layer 31 and includes the heterogeneous gallium nitride based material having the wider energy bandgap that that of the first nitride layer 31. In this configuration, the second nitride layer 33 serves to supply electrons to the 2DEG channel 35 formed in the first nitride layer 31. As one example, the second nitride layer 33 donating electrons may be formed at a thickness thinner than that of the first nitride layer 31.

Preferably, according to the exemplary embodiment of the present invention, the first nitride layer 31 contains gallium nitride (GaN) and the second nitride layer 33 contains any one of aluminum gallium nitride (AlGaN), indium gallium nitride (InGaN), and indium aluminum gallium nitride (InAlGaN). Preferably, according to the exemplary embodiment of the present invention, the first nitride layer 31 contains gallium nitride (GaN) and the second nitride layer 33 includes the aluminum gallium nitride (AlGaN).

Continuously, the configurations of the exemplary embodiment of the present invention will be described in more detail with reference to FIGS. 1, 2A and 2B, 5A and 5B or/and 6A and 6B.

Referring to FIGS. 1, 2A and 2B, 5A and 5B, or/and 6A and 6B, the drain electrode 50 and the source electrode 60 of the nitride semiconductor device according to the exemplary embodiment of the present invention are disposed on the nitride semiconductor layer 30. The drain electrode 50 is ohmic-contacted 50a with the nitride semiconductor layer 30.

The source electrode 60 is disposed to be spaced apart from the drain electrode 50, includes a plurality of patterned protrusion portions 61 protruded to a drain electrode direction, and is Schottky-contacted 60a to the nitride semiconductor layer 30. The plurality of patterned protrusion portions 61 may have, for example, a squared saw-teeth shape pattern. A flow of reverse current is interrupted by forming the nitride semiconductor layer 30 on the lower thereof, in more detail, a depletion region in the second nitride layer 33 according to the Schottky junction by the plurality of patterned protrusion portions 61 that are characteristics of the present invention. When the nitride semiconductor device is driven by the reverse bias according to the structure of the source electrode 60 that is Schottky-contacted 60a, the depletion region generated by the Schottky junction region 60a of the source electrode 60 is expanded to interrupt the 2DEG channel 35, thereby stably interrupting the flow of current. Therefore, the flow of reverse current is interrupted to increase the reverse breakdown current, thereby implementing the normally-off state. In particular, when the reverse bias voltage is applied, the depletion region is largely expanded in the Schottky junction region 60a around a corner of the drain direction side of the source electrode 60. Meanwhile, when the forward bias voltage is applied, the depletion region generated in the Schottky junction region 60a of the source electrode 60 is small, such that current flows between the drain electrode 50 and the source electrode 60 through the 2DEG channel 35.

Further, in the exemplary embodiment of the present invention, as shown in FIGS. 1, 2A and 2B, 5A and 5B, or/and 6A and 6B, the source electrode 60 is disposed on the lower end of the source electrode 60 by including the ohmic patterns 65 that are ohmic-contacted 65a with the nitride semiconductor layer 30. According to the characteristics of the present invention, the turn-on resistance is reduced by increasing current through the ohmic pattern electrode 65 between the Schottky junction 60a patterns at the interface surface of the lower end of the source electrode 60, thereby implementing the high current operation. As shown in FIG. 1, the ohmic pattern electrode 65 may be a bar shape and although not shown, the bar-shaped ohmic pattern electrode 65 may be disposed in plural. Alternatively, although not shown, the ohmic pattern electrode 65 may be formed so that a plurality of small bar patterns form a line.

Describing another exemplary embodiment of the present invention with reference to FIG. 1, the ohmic pattern 65 is disposed in parallel with the arrangement of the drain electrode 50.

According to another exemplary embodiment of the present invention, a portion of at least a drain direction side of the ohmic pattern 65 is contacted to the dielectric layer 40 on at least wall sections of the recess regions formed by the plurality of patterned protrusion portions 61. Therefore, only a portion in the drain direction side of the ohmic pattern 65 may be contacted to the dielectric layer 40 only on the wall sections of the recess regions formed by the plurality of patterned protrusion portions 61 and a portion of the region in the drain direction of the ohmic pattern 65 may be exposed up to the recess regions formed by the plurality of patterned protrusion portions 61 so as to be contacted to the dielectric layer 40.

As an aspect of another detailed exemplary embodiment of the present invention, a portion of the region in the drain direction of the ohmic pattern 65 is contacted to the dielectric layer 40 in the recess regions formed by the plurality of patterned protrusion portions 61. In this case, when the region of the ohmic pattern 65 contacted to the dielectric layer 40 by being exposed up to the recess regions formed by the plurality of patterned protrusion portions 61 is increased, current may be easily increased so as to implement the high current operation but increase the leakage current. Therefore, when the ohmic pattern 65 is exposed up to the recess regions formed by the patterned protrusion portions 61, the ohmic pattern 65 is exposed within an appropriate range experimentally obtained from the relationship between the increase in current and the leakage current.

Although not shown, as an example, the ohmic pattern 65 ohmic-contacted 65a to the nitride semiconductor layer 30 may be disposed to be enclosed by the source electrode 60, all of which are Schottky-contacted.

Continuously, referring to FIGS. 1, 2A and 2B, 5A and 5B, or/and 6A and 6B, the dielectric layer 40 of the nitride semiconductor device according to the exemplary embodiment of the present invention is disposed on the nitride semiconductor layer 30 between the drain electrode 50 and the source electrode 60 and is disposed over at least a portion of the source electrode 60, including the patterned protrusion portions 61. As an example, the dielectric layer 40 is disposed over the nitride semiconductor layer 30 between the drain electrode 50 and the source electrode 60 and is disposed over the entire region of the patterned protrusion portions 61 of the source electrode 60 and a portion of the region of the other source electrode 60.

Preferably, according to another exemplary embodiment of the present invention, as shown in FIGS. 1, 2A and 2B, 5A and 5B, or/and 6A and 6B, the dielectric layer 40 may be made of an oxide layer and according to the exemplary embodiment of the present invention, may be made of at least one of SiN, SiO₂, and Al₂O₃.

Continuously, referring to FIGS. 1, 2A and 2B, 5A and 5B, or/and 6A and 6B, the gate electrode 70 of the nitride semiconductor device according to the exemplary embodiment of the present invention are disposed on the dielectric layer 40 so as to be spaced apart from the drain electrode 50. Further, referring to FIGS. 1, 2A and 2B, 5A and 5B, or/and 6A and 6B, a portion 71 of the gate electrode 70 is disposed on the dielectric layer 40 over the patterned protrusion portions 61 and the drain direction edge portion of the source electrode 60. The gate electrode 70 is Schottky-contacted 70a on the dielectric layer 40. When the forward bias voltage is applied to the gate electrode 70, the depletion region generated in the Schottky junction region 60a around the drain direction side corner of the source electrode 60 is small, such that current flows between the drain electrode 50 and the source electrode 60 through the 2DEG channel 35.

According to another exemplary embodiment of the present invention with reference to FIGS. 1, 2A and 2B, 5A and 5B, or/and 6A and 6B, the patterned protrusion portions 61 and portions 71 and 71′ of the gate electrode formed on the upper portion of the drain direction edge portion of the source electrode 60 are formed to cover at least a portion of the ohmic pattern 65 of the source electrode 60.

Referring to FIGS. 1, 2A and 2B, 5A and 5B, or/and 6A and 6B, the gate structure is covered on the upper portion of edge portion of the source electrode 60 and the dielectric layer 40 between the drain electrode 50 and the source electrode 60 to disperse electric field, such that the gate structure itself serves as a field plate increasing withstand voltage.

In addition, another exemplary embodiment of the present invention will be described with reference to FIGS. 2A and 2B or/and 6A and 6B.

Referring to FIGS. 2A and 2B or/and 6A and 6B, the nitride semiconductor device according to the exemplary embodiment of the present invention is configured to include the nitride semiconductor layer 30, the drain electrode 50, the source electrode 60, the dielectric layer 40, and the gate electrode 70, which are disposed over the substrate 10. The nitride semiconductor layer 30, the drain electrode 50, the source electrode 60, and the dielectric layer 40 will refer to the above descriptions.

In the exemplary embodiment of the present invention, the gate electrode 70 includes the first regions 71 and 71′ and second regions 73 and 73′. The first regions 71 and 71′ are disposed on the dielectric layer 40 over the patterned protrusion portions 61 and the drain direction edge portion of the source electrode 60. The second regions 73 and 73′ are disposed on the dielectric layer 40 between the drain electrode 50 and the source electrode 60 so as to be spaced apart from the drain electrode 50. The first regions and the second regions may be integrally formed as shown in FIGS. 2A and 2B and may be separated from each other as shown in FIGS. 6A and 6B.

Referring to FIGS. 2A and 2B or/and 6A and 6B, in another exemplary embodiment of the present invention, the first regions 71 and 71′ are formed to cover at least a portion of the ohmic pattern 65 of the source electrode 60.

Describing another exemplary embodiment of the present invention with reference to FIGS. 6A and 6B, the first region 71′ and the second region 73′ of the gate electrode 70 are separated from each other. In this configuration, the second region 73′ forms a floating gate. Since the second region 73′ serves as the floating gate, the electric field may be dispersed by the second region 73′. The second region 73′ may be closely disposed to the source electrode 60.

Although not shown, according to another exemplary embodiment of the present invention, the ohmic pattern electrode 65 of the nitride semiconductor device having the structure of the gate electrode 70 separated into the first region 71′ and the second region 73′ is disposed in parallel with the arrangement of the drain electrode 50 as shown in FIG. 1. The ohmic pattern electrode 65 is disposed in the region of the source electrode 60 to apply the forward bias voltage, thereby lowering the turn-on resistance and implementing the high current operation.

Although not shown in FIGS. 6A and 6B, according to another exemplary embodiment of the present invention, the buffer layer 20 may be provided between the substrate 10 and the nitride semiconductor layer 30 and the nitride semiconductor layer 30 may be disposed on the buffer layer 20, similar to ones shown in FIGS. 5A and 5B.

According to the exemplary embodiment of the present invention as shown in FIGS. 1, 2A and 2B, 5A and 5B, or/and 6A and 6B, when the voltage of 0V is applied to the gate electrode 70, the flow of current through the 2DEG channel 35 between the drain electrode 50 and the source electrode 60 is interrupted by the Schottky barrier in the region of the source electrode 60. Further, when the threshold voltage or more is applied to the gate electrode 70, the carrier (electron) concentration is increased in the drain direction edge region of the source electrode 60 to move current due to the tunneling phenomenon. In this case, the threshold voltage of the gate is determined by the thickness of the dielectric layer 40, or the like. Therefore, the manufacturing is more easily facilitated, the leakage current is smaller, and the higher voltage characteristic is shown, as compared with the existing normally-off HEMT structure.

According to the exemplary embodiment of the present invention, the interface surface in the drain direction of the Schottky source electrode 60 is provided with the plurality of patterned protrusion portions 61 having, for example, the saw-teeth shape. Meanwhile, the region of the source electrode 60 is provided with the ohmic pattern electrode 65 having, for example, the line shape to increase the current through the ohmic contact 65a, thereby lowering the turn-on resistance and implementing the high current operation.

According to another exemplary embodiment of the present invention, the nitride semiconductor device according to the above-mentioned exemplary embodiments is a power transistor device. The power transistor according to the exemplary embodiment of the present invention includes a horizontal HEMT structure.

Next, a method for manufacturing a nitride semiconductor according to another exemplary embodiment of the present invention will be described with reference to the drawings. In describing the method for manufacturing a nitride semiconductor according to the exemplary embodiment of the present invention, FIGS. 3A to 3D, 4A to 4D and the nitride semiconductor device mentioned in the above exemplary embodiments and FIGS. 1, 2A and 2B, 5A and 5B, or/and 6A and 6B will be referenced, and vice versa.

FIGS. 3A to 3D, and 4A to 4D show the methods for manufacturing a nitride semiconductor according to the exemplary embodiment of the present invention.

According to the exemplary embodiment of the present invention, the device manufactured by the method for manufacturing a nitride semiconductor device of the present invention is the power transistor.

First, referring to FIGS. 3A and 4A, the nitride semiconductor layer 30 generating the two-dimensional electron gas (2DEG) channel 35 is disposed over the substrate 10. Preferably, the substrate 10 may be made of at least any one of silicon (Si), silicon carbide (SiC), and sapphire (Al₂O₃). As nitrides forming the nitride semiconductor layer 30, gallium nitride (GaN), aluminum gallium nitride (AlGaN), indium nitride gallium (InGaN), or indium aluminum gallium nitride (InAlGaN), or the like, are used.

Preferably, the nitride semiconductor layer 30 may be formed by epitaxially growing the nitride single crystal thin film. Preferably, a control is performed to prevent the overgrowth by selectively growing the nitride single crystal thin film at the time of the expitaxial growth. If the nitride single crystal thin film is overgrown, a planarization process may be added using an etch back process or a chemical mechanical polishing (CMP) process.

According to another exemplary embodiment of a method for manufacturing a nitride semiconductor of the present invention, the first nitride layer 31 and the second nitride layer 33 shown in FIG. 3A are formed by the epitaxial growth process. First, the first nitride layer 31 is disposed over the substrate 10 by epitaxially growing gallium nitride based single crystal thin film. Preferably, according to the exemplary embodiment of the present invention, the first nitride layer 31 is formed by epitaxially growing gallium nitride (GaN). Next, the second nitride layer 33 is formed by epitaxially growing the nitride layer including the heterogeneous gallium nitride based materials having the energy bandgap wider than that of the first nitride layer 31 using the first nitride layer 31 as the seed layer. Preferably, according to another exemplary embodiment of the present invention, the second nitride layer 33 is formed by epitaxially growing gallium nitride based single crystal including any one of aluminum gallium nitride (AlGaN), indium gallium nitride (InGaN), and indium aluminum gallium nitride (InAlGaN). Preferably, the second nitride layer 33 is formed by epitaxially growing the aluminum gallium nitride (AlGaN). As an example, the second nitride layer 33 donating electrons may be formed at a thinner thickness than that of the first nitride layer 31.

As the epitaxial growth process for forming the first and second nitride layer 33, the liquid phase epitaxy (LPE), the chemical vapor deposition (CVD), the molecular beam epitaxy (MBE), the metalorganic CVD (MOCVD), or the like, may be used.

Next, referring to FIGS. 3B and 4B, the drain electrode 50 and the source electrode 60 are disposed on the nitride semiconductor layer 30. In FIGS. 3B, the drain electrode 50 is formed so as to be ohmic-contacted 50a with the nitride semiconductor layer 30. The heat treatment may be performed so as to complete the ohmic junction. The drain metal electrode is disposed on the nitride semiconductor layer 30 using at least one metal of gold (Au), nickel (Ni), platinum (Pt), titanium (Ti), aluminum (Al), palladium (Pd), iridium (Ir), rhodium (Rh), cobalt (Co), tungsten (W), molybdenum (Mo), tantalum (Ta), copper (Cu), and zinc (Zn), metal silicide, and an alloy thereof. The drain electrode 50 may be formed in the multi layer structure.

The source electrode 60 is spaced apart from the drain electrode 50, includes the plurality of patterned protrusion portions 61 protruded to the drain electrode direction, and is formed so as to be Schottky-contacted 60a to the nitride semiconductor layer 30. The flow of reverse current is interrupted by forming the nitride semiconductor layer 30 on the lower thereof, in more detail, the depletion region in the second nitride layer 33 according to the Schottky junction by the plurality of patterned protrusion portions 61 that are characteristics of the present invention. The source electrode 60 Schottky-contacted 60a may form the metal electrode using materials that may be Schottky-contacted with the nitride semiconductor layer 30, for example, at least one metal of aluminum (Al), molybdenum (Mo), gold (Au), nickel (Ni), platinum (Pt), titanium (Ti), palladium (Pd), iridium (Ir), rhodium (Rh), cobalt (Co), tungsten (W), tantalum (Ta), copper (Cu), and zinc (Zn), a metal silicide, and an alloy thereof. The source electrode 60 may be formed in the multi layer structure.

Further, at the forming of the source electrode 60 according to the exemplary embodiment of the present invention, as shown in FIG. 3B, the source electrode 60 is formed by disposing the ohmic pattern 65 ohmic-contacted 65a with the nitride semiconductor layer 30 on the lower end of the source electrode 60. In this configuration, the turn-on resistance is reduced by increasing current through the ohmic pattern electrode 65 between the Schottky junction 60a patterns at the interface surface of the lower end of the source electrode 60, thereby implementing the high current operation.

Describing another exemplary embodiment of the present invention with reference to FIG. 1, at the forming of the source electrode 60, the ohmic pattern 65 is disposed in parallel with the arrangement of the drain electrode 50.

According to another exemplary embodiment of the present invention, at the forming of the source electrode 60, a portion of at least the drain direction side of the ohmic pattern 65 is exposed on at least the wall sections of the recess regions formed by the plurality of patterned protrusion portions 61. Further, at the forming of the dielectric layer 40, the dielectric layer 40 is formed so that a portion of at least the drain direction side of the ohmic pattern exposed on at least the wall sections of the recess regions formed by the plurality of patterned protrusion portions 61 is contacted to the dielectric layer 40. Therefore, only a portion in the drain direction side of the ohmic pattern 65 may be contacted to the dielectric layer 40 only on the wall sections of the recess regions formed by the plurality of patterned protrusion portions 61 and a portion of the region in the drain direction of the ohmic pattern 65 is exposed up to the recess regions formed by the plurality of patterned protrusion portions 61 so as to be contacted to the dielectric layer 40.

According to another exemplary embodiment of the present invention, at the forming of the source electrode 60, a portion in the drain direction of the ohmic pattern 65 is exposed in the recess regions formed by the plurality of patterned protrusion portions 61. Further, at the forming of the dielectric layer 40, the dielectric layer 40 is formed so that the portion in the drain direction of the ohmic pattern exposed in the recess regions formed by the plurality of patterned protrusion portions 61 is contacted with the dielectric layer 40.

Although not shown, as an example, at the forming of the source electrode 60, the entire of the ohmic pattern 65 ohmic-contacted 65a with the nitride semiconductor layer 30 may be disposed so as to be enclosed by the source electrode 60 Schottky-contacted.

Describing the process of forming the drain electrode 50 and the source electrode 60 according to the exemplary embodiment of the present invention, the metal layer for forming the electrode on the nitride semiconductor layer 30 epitaxially grown on the upper portion of the substrate 10 is deposited by an electronic beam evaporator, or the like, and the photoresist pattern is disposed on the metal layer. Further, the metal electrodes 50 and 60 may be formed by etching the metal layer using the photoresist pattern as the etch mask and removing the photoresist pattern.

In this case, according to another exemplary embodiment of the present invention, the Schottky junction electrode is formed in the remaining area of the source electrode 60 after the ohmic pattern electrode 65 having the predetermined pattern is formed in a portion of the region of the source electrode 60 by an additional ohmic metal deposition process simultaneously with or after forming the drain ohmic electrode 50. At the time of forming the Schottky junction source electrode 60 in the remaining region, the plurality of patterned protrusion portions 61 is formed using the photoresist pattern.

Referring to FIGS. 3C and 4C, in the exemplary embodiment of the present invention, after the drain electrode 50 and the source electrode are formed, the dielectric layer 40 is disposed on the nitride semiconductor layer 30 between the drain electrode 50 and the source electrode 60. In this case, the dielectric layer 40 is disposed over a portion of at least source electrode 60, preferably, the entire of the patterned protrusion portions 61 of the source electrode 60 and a portion of the region of the source electrode 60 in the drain direction, including the patterned protrusion portions 61 of the source electrode 60. Preferably, the dielectric layer 40 may be formed of the oxide layer. According to the exemplary embodiment of the present invention, the dielectric layer 40 may be made of any one of SiN, SiO₂, and Al₂O₃.

Referring to FIGS. 3D and 4D, in the exemplary embodiment of the present invention, the gate electrode 70 is disposed on the dielectric layer 40 so as to be spaced apart from the drain electrode 50 after the dielectric layer 40 according to FIGS. 3C and 4C is formed. In this case, referring to FIGS. 3D and 4D, a portion 71 of the gate electrode 70 is disposed on the dielectric layer 40 over the patterned protrusion portions 61 and the drain direction edge portion of the source electrode 60. The gate electrode 70 may form the metal electrode using at least one metal of aluminum (Al), molybdenum (Mo), gold (Au), nickel (Ni), platinum (Pt), titanium (Ti), palladium (Pd), iridium (Ir), rhodium (Rh), cobalt (Co), tungsten (W), tantalum (Ta), copper (Cu), and zinc (Zn), a metal silicide, and an alloy thereof. The gate electrode 70 may use metals different from the drain electrode 50 or/and the source electrode 60 and may be formed in the multilayer structure. Preferably, the gate electrode 70 is Schottky-contacted 70a on the dielectric layer 40.

According to another exemplary embodiment of the present invention, at the forming of the gate electrode 70, the portions 71 and 71′ of the gate electrode 70 formed over the patterned protrusion portions 61 and the drain direction edge portion of the source electrode 60 are formed to cover at least a portion of the ohmic pattern 65 of the source electrode 60.

Describing the process of forming the gate electrode 70 according to the exemplary embodiment of the present invention, the metal layer for forming the electrode on the dielectric layer 40 is deposited by the electronic beam evaporator, or the like, the photoresist pattern is formed on the metal layer so that a portion of the gate electrode 70 is disposed on the dielectric layer 40 over the patterned protrusion portions 61 and the drain direction edge portion of the source electrode 60. Further, the metal layer is etched by using the photoresist pattern as the etch mask. The metal electrode is formed by removing the photoresist pattern after the etching.

Further, describing another exemplary embodiment of the present invention with reference to FIGS. 3D and 4D, and FIGS. 6A and 6B, the gate electrode 70 includes the first region 71 and the second region 73. The first region 71 of the gate electrode 70 is disposed on the dielectric layer 40 over the patterned protrusion portions 61 and the drain direction edge portion of the source electrode 60. The second region 73 forms the gate electrode 70 on the dielectric layer 40 between the drain electrode 50 and the source electrode 60 so as to be spaced apart from the drain electrode 50. The first region 71 and the second region 73 may be integrally formed as shown in FIGS. 3D and 4D and may be separated from each other as shown in FIGS. 6A and 6B.

Describing another exemplary embodiment of the present invention with reference to FIGS. 3D and 4D, and FIGS. 6A and 6B, at the forming of the gate electrode 70, the first regions 71 and 71′ are formed to cover at least a portion of the ohmic pattern 65 of the source electrode 60.

Describing another exemplary embodiment of the present invention with reference to FIGS. 6A and 6B, at the forming of the gate electrode 70, the gate electrode 70 is formed by separating the first region 71 and the second region 73, wherein the second region 73 is formed as the floating gate on the dielectric layer 40 between the drain electrode 50 and the source electrode 60.

According to the exemplary embodiment of the method for manufacturing a nitride semiconductor according to the exemplary embodiment of the present invention, referring to FIGS. 5A and 5B, the method for manufacturing a nitride semiconductor may further include forming a buffer layer 20 on the substrate 10 prior to forming the nitride semiconductor layer 30 on the upper portion of the substrate 10 shown in FIG. 6A. The buffer layer 20 is provided so as to solve the problems due to the lattice mismatch between the substrate 10 and the nitride semiconductor layer 30. The buffer layer 20 may be formed in a single layer or several layers including gallium nitride (GaN), aluminum gallium nitride (AlGaN), aluminum nitride (AlN), indium gallium nitride (InGaN), indium aluminum gallium nitride (InAlGaN), or the like.

As set forth above, the exemplary embodiment of the present invention can obtain the semiconductor device capable of being operated in the normally-off (N-off) or the enhancement mode and operated at high voltage and high current by forming the Schottky electrode in the source region of the semiconductor device, for example, the FET, providing the plurality of patterned protrusion portions protruded in the drain direction, providing the ohmic pattern electrodes ohmic-contacted at the interface surface of the lower end thereof, and forming the portion of the gate electrode on the upper portion of a portion of the region of the source electrode.

The semiconductor device and the method for manufacturing the same according to the exemplary embodiment of the present invention can be operated at higher voltage and higher current than the existing GaN normally-off (N-off) device and simplify the manufacturing process to easily manufacture the semiconductor device. That is, the exemplary embodiment of the present invention can easily manufacture the semiconductor device since the complex process such as the ion implantation of the normally-off (N-off) HEMT of the related art, the AlGaN layer etching of the thickness of 200 to 300 Å, or the like, is not required.

In addition, the exemplary embodiment of the present invention can prevent current from being leaked by the Schottky barrier of the source electrode to further reduce the leakage current and further increase the voltage than the existing normally-off (N-off) HEMT. Further, according to the exemplary embodiment of the present invention, the ohmic junction of the ohmic pattern electrodes is implemented between the Schottky junction patterns at the interface surface of the lower end of the Schottky source electrode to increase current through the ohmic contact, thereby lowering the turn-on resistance and implement the high-current operation.

In addition, according to the exemplary embodiment of the present invention, the gate structure is formed on the upper portion of the edge portion of the source electrode and the dielectric layer between the drain electrode and the source electrode to disperse the electric field so as to serve as the field plate increasing the voltage and the distance between the source electrode and the gate electrode is short to increase the transconductance.

It is obvious that various effects directly stated according to various exemplary embodiment of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

What is claimed is:

1. A nitride semiconductor device, comprising:
a nitride semiconductor layer that is disposed over a substrate and has a two dimensional electron gas (2DEG) channel formed therein;
a drain electrode that is ohmic-contacted with the nitride semiconductor layer;
a source electrode that is disposed to be spaced apart from the drain electrode, includes a plurality of patterned protrusion portions protruded to the drain electrode direction, is Schottky-contacted with the nitride semiconductor layer, and includes an ohmic pattern ohmic-contacted with the nitride semiconductor layer on a lower end thereof;
a dielectric layer that is disposed on the nitride semiconductor layer between the drain electrode and the source electrode and over at least a portion of the source electrode, wherein the portion of the source electrode includes the patterned protrusion portions; and
a gate electrode that is disposed on the dielectric layer so as to be spaced apart from the drain electrode, wherein a portion of the gate electrode is disposed on the dielectric layer over the patterned protrusion portions and a drain direction edge portion of the source electrode.

2. The nitride semiconductor device according to claim 1, wherein a portion of at least a drain direction side of the ohmic pattern is contacted with the dielectric layer on at least wall sections of the recess regions formed by the plurality of patterned protrusion portions.

3. The nitride semiconductor device according to claim 1, wherein a portion in the drain direction of the ohmic pattern is contacted with the dielectric layer in the recess regions formed by the plurality of patterend protrusion portions.

4. The nitride semiconductor device according to claim 1, wherein a portion of the gate electrode formed over the patterned protrusion portions and the drain direction edge portion of the source electrode is formed to cover at least a portion of the ohmic pattern of the source electrode.

5. The nitride semiconductor device according to claim 1, wherein the ohmic pattern is disposed in parallel with an arrangement of the drain electrode.

6. The nitride semiconductor device according to claim 1, wherein the nitride semiconductor layer includes:
a first nitride layer that is disposed over the substrate and includes a gallium nitride based material; and
a second nitride layer that is heterogeneous-junctioned on the first nitride layer and contains a heterogeneous gallium nitride based material having an energy bandgap wider than that of the first nitride layer.

7. The nitride semiconductor device according to claim 6, wherein the first nitride layer contains gallium nitride (GaN), and
the second nitride layer contains any one of aluminum gallium nitride (AlGaN), indium gallium nitride (InGaN), and indium aluminum gallium nitride (InAlGaN).

8. A nitride semiconductor device, comprising:
a nitride semiconductor layer that is disposed over a substrate and has a two dimensional electron gas (2DEG) channel formed therein;
a drain electrode that is ohmic-contacted with the nitride semiconductor layer;
a source electrode that is disposed to be spaced apart from the drain electrode, includes a plurality of patterned protrusion portions protruded to the drain electrode direction, is Schottky-contacted with the nitride semiconductor layer, and includes an ohmic pattern ohmic-contacted with the nitride semiconductor layer on a lower end thereof;
a dielectric layer that is disposed on the nitride semiconductor layer between the drain electrode and the source electrode and over at least a portion of the source electrode, wherein the portion of the source electrode includes the patterned protrusion portions; and
a gate electrode that includes a first region formed on the dielectric layer over the patterned protrusion portions and a drain direction edge portion of the source electrode and a second region disposed on the dielectric layer between the drain electrode and the source electrode so as to be spaced apart from the drain electrode.

9. The nitride semiconductor device according to claim 8, wherein a portion of at least the drain direction side of the ohmic pattern is contacted with the dielectric layer on at least wall sections of the recess regions formed by the plurality of patterned protrusion portions.

10. The nitride semiconductor device according to claim 8, wherein a portion in the drain direction of the ohmic pattern is contacted with the dielectric layer in the recess regions formed by the plurality of patterend protrusion portions.

11. The nitride semiconductor device according to claim 8, wherein the gate electrode is separated into the first region and the second region, the second region forming a floating gate.

12. The nitride semiconductor device according to claim 11, wherein the first region is formed to cover at least a portion of the ohmic pattern of the source electrode.

13. The nitride semiconductor device according to claim 11, wherein the ohmic pattern is disposed in parallel with an arrangement of the drain electrode.

14. The nitride semiconductor device according to claim 11, wherein the nitride semiconductor layer includes:
a first nitride layer that is disposed over the substrate and includes a gallium nitride based material; and
a second nitride layer that is heterogeneous-junctioned on the first nitride layer and contains a heterogeneous gallium nitride based material having an energy bandgap wider than that of the first nitride layer.

15. The nitride semiconductor device according to claim 1, further comprising a buffer layer between the substrate and the nitride semiconductor layer.

16. The nitride semiconductor device according to claim 8, further comprising a buffer layer between the substrate and the nitride semiconductor layer.

17. The nitride semiconductor device according to claim 1, wherein the substrate uses at least any one of silicon (Si), silicon carbide (SiC), and sapphire (Al₂O₃).

18. The nitride semiconductor device according to claim 8, wherein the substrate uses at least any one of silicon (Si), silicon carbide (SiC), and sapphire (Al₂O₃).

19. The nitride semiconductor device according to claim 1, wherein the dielectric layer is made of at least any one of SiN, SiO₂, and Al₂O₃.

20. The nitride semiconductor device according to claim 8, wherein the dielectric layer is made of at least any one of SiN, SiO₂, and Al₂O₃.

21. The nitride semiconductor device according to claim 1, wherein the nitride semiconductor device is a power transistor device.

22. The nitride semiconductor device according to claim 8, wherein the nitride semiconductor device is a power transistor device.

23. A method for manufacturing a nitride semiconductor device, comprising:
generating a nitride semiconductor layer that is disposed over a substrate and has a two dimensional electron gas (2DEG) channel formed therein;
forming a drain electrode that is ohmic-contacted with the nitride semiconductor layer and forming a source electrode that is disposed to be spaced apart from the drain electrode, includes a plurality of patterned protrusion portions protruded to the drain electrode direction, is Schottky-contacted with the nitride semiconductor layer, and includes an ohmic pattern ohmic-contacted with the nitride semiconductor layer on a lower end thereof;
forming a dielectric layer that is disposed on the nitride semiconductor layer between the drain electrode and the source electrode and over at least a portion of the source electrode, wherein the portion of the source electrode includes the patterned protrusion portions; and
forming a gate electrode on the dielectric layer so as to be spaced apart from the drain electrode, wherein a portion of the gate electrode is disposed on the dielectric layer over the patterned protrusion portions and a drain direction edge portion of the source electrode.

24. The method according to claim 23, wherein at the forming of the source electrode, a portion of at least a drain direction side of the ohmic pattern is exposed on at least wall sections of the recess regions formed by the plurality of patterned protrusion portions, and
at the forming of the dielectric layer, the dielectric layer is formed so that the exposed portion of at least a drain direction side of the ohmic pattern is contacted with the dielectric layer.

25. The method according to claim 23, wherein at the forming of the source electrode, a portion in the drain direction of the ohmic pattern is exposed in the recess regions formed by the plurality of patterned protrusion portions, and
at the forming of the dielectric layer, the dielectric layer is formed so that the exposed portion in the drain direction of the ohmic pattern is contacted with the dielectric layer.

26. The method according to claim 23, wherein at the forming of the gate electrode, a portion of the gate electrode formed over the patterned protrusion portions and the drain direction edge portion of the source electrode is formed so as to cover at least a portion of the ohmic pattern of the source electrode.

27. A method for manufacturing a nitride semiconductor device, comprising:
generating a nitride semiconductor layer that is disposed over a substrate and has a two dimensional electron gas (2DEG) channel formed therein;
forming a drain electrode that is ohmic-contacted with the nitride semiconductor layer and forming a source electrode that is disposed to be spaced apart from the drain electrode, includes a plurality of patterned protrusion portions protruded to the drain electrode direction, is Schottky-contacted with the nitride semiconductor layer, and includes an ohmic pattern ohmic-contacted with the nitride semiconductor layer on a lower end thereof;
forming a dielectric layer that is disposed on the nitride semiconductor layer between the drain electrode and the source electrode and over at least a portion of the source electrode, wherein the portion of the source electrode includes the patterned protrusion portions; and
forming a gate electrode that includes a first region formed on the dielectric layer over the patterned protrusion portions and a drain direction edge portion of the source electrode and a second region disposed on the dielectric layer between the drain electrode and the source electrode so as to be spaced apart from the drain electrode.

28. The method according to claim 27, wherein at the forming of the source electrode, a portion of at least a drain direction side of the ohmic pattern is exposed on at least wall sections of the recess regions formed by the plurality of patterned protrusion portions, and
at the forming of the dielectric layer, the dielectric layer is formed so that the exposed portion of at least a drain direction side of the ohmic pattern is contacted with the dielectric layer.

29. The method according to claim 27, wherein at the forming of the source electrode, a portion in the drain direction of the ohmic pattern is exposed in the recess regions formed by the plurality of patterned protrusion portions, and
at the forming of the dielectric layer, the dielectric layer is formed so that the exposed portion in the drain direction of the ohmic pattern is contacted with the dielectric layer.

30. The method according to claim 27, wherein at the forming of the gate electrode, the gate electrode is formed by separating the first region from the second region, the second region being formed as the floating gate on the dielectric layer between the drain electrode and the source electrode.
